(19) United States
(12) Patent Application Publication
(10) Pub. No.: US 2024/0347320 A1
(43) Pub. Date: Oct. 17, 2024

(54) PLASMA PROCESSING APPARATUS, POWER SYSTEM, CONTROL METHOD, AND STORAGE MEDIUM

(71) Applicant: Tokyo Electron Limited, Tokyo (JP)

(72) Inventor: Chishio KOSHIMIZU, Miyagi (JP)

(73) Assignee: Tokyo Electron Limited, Tokyo (JP)

(21) Appl. No.: 18/755,874

(22) Filed: Jun. 27, 2024

Related U.S. Application Data
(63) Continuation of application No. PCT/JP2022/047216, filed on Dec. 21, 2022.

(30) Foreign Application Priority Data
Dec. 27, 2021 (JP) 2021-212599

(51) Int. Cl. H01J 37/32

(52) U.S. Cl. CPC H01J 37/32165; H01J 37/32146

(57) ABSTRACT

A plasma processing apparatus includes a chamber, a substrate support, a bias power supply, and a radio-frequency power supply. The bias power supply is electrically coupled to the substrate support and generates electrical bias energy. The radio-frequency power supply is electrically connected to a radio-frequency electrode and generates source radio-frequency power to generate plasma from a gas within the chamber. The bias power supply changes a bias frequency of the electrical bias energy at least once during a process. The radio-frequency power supply changes a source frequency of the source radio-frequency power to reduce a degree of reflection of the source radio-frequency power within a waveform period of the electrical bias energy during the process.

### CROSS-REFERENCE TO RELATED APPLICATIONS

This application is a continuation application of International Patent Application No. PCT/JP2022/047216, filed on Dec. 21, 2022, which claims priority from Japanese Patent Application No. 2021-212599, filed on Dec. 27, 2021, with the Japan Patent Office, all of which are incorporated herein in their entireties by reference.

### TECHNICAL FIELD

Embodiments of the present disclosure relate to a plasma processing apparatus, a power system, a control method, a program, and a storage medium.

### BACKGROUND

Plasma processing apparatuses are used for plasma processing of substrates. In the plasma processing apparatuses, bias radio-frequency power is used to introduce ions from plasma generated within a chamber into a substrate. Japanese Patent Publication No. 2009-246091 discloses a plasma processing apparatus that synchronizes pulse modulation of a power level of bias radio-frequency power and pulse modulation of a frequency of the bias radio-frequency power.

### SUMMARY

In an embodiment, a plasma processing apparatus is provided and includes a chamber, a substrate support, a bias power supply, and a radio-frequency power supply. The substrate support is provided within the chamber. The bias power supply is electrically coupled to the substrate support and generates electrical bias energy. The radio-frequency power supply is electrically connected to a radio-frequency electrode and generates source radio-frequency power to generate plasma from a gas within the chamber. The bias power supply changes a bias frequency of the electrical bias energy at least once during a process. The radio-frequency power supply changes a source frequency of the source radio-frequency power to reduce a degree of reflection of the source radio-frequency power within a waveform period of the electrical bias energy having a time length that is a reciprocal of the bias frequency during the process.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 illustrates a configuration of a plasma processing system according to an embodiment of the present disclosure.

FIG. 2 illustrates a configuration of a capacitively coupled plasma processing apparatus according to an embodiment of the present disclosure.

FIG. 3 illustrates a configuration of a power system in a plasma processing apparatus according to an embodiment of the present disclosure.

FIG. 4 illustrates a timing chart related to a plasma processing apparatus according to an embodiment of the present disclosure.

FIG. 5 illustrates a timing chart related to a plasma processing apparatus according to an embodiment of the present disclosure.

FIG. 6 illustrates a timing chart related to a plasma processing apparatus according to an embodiment of the present disclosure.

FIG. 7 illustrates a timing chart related to a plasma processing apparatus according to an embodiment of the present disclosure.

FIG. 8 a timing chart related to a plasma processing apparatus according to an embodiment of the present disclosure.

FIG. 9 is a flowchart of a control method according to an embodiment of the present disclosure.

### DETAILED DESCRIPTION

In the following detailed description, reference is made to the accompanying drawings, which form a part thereof. The illustrative embodiments described in the detailed description, drawings, and claims are not meant to be limiting. Other embodiments may be used, and other changes may be made without departing from the spirit or scope of the subject matter presented here.

Hereinafter, various embodiments of the present disclosure will be described with reference to the drawings.

In an embodiment, a plasma processing apparatus is provided and includes a chamber, a substrate support, a bias power supply, and a radio-frequency power supply. The substrate support is provided in the chamber. The bias power supply is electrically coupled to the substrate support and generates electrical bias energy. The radio-frequency power supply is electrically connected to a radio-frequency electrode and generates source radio-frequency power, thereby generating plasma from a gas within the chamber. The bias power supply changes a bias frequency of the electrical bias energy at least once during a process. The radio-frequency power supply changes a source frequency of the source radio-frequency power to reduce a degree of reflection of the source radio-frequency power within a waveform period of the electrical bias energy having a time length that is a reciprocal of the bias frequency, during the process.

According to the embodiment, during the process, the bias frequency of the electrical bias energy changes as the process progresses. The source frequency changes within the waveform period of the electrical bias energy to reduce the degree of reflection of the source radio-frequency power within the waveform period of the electrical bias energy. Thus, according to the embodiment, it is possible to change the bias frequency as the process progresses and further reduce the degree of reflection of the source radio-frequency power.

In an embodiment, the radio-frequency power supply may use a plurality of frequencies included in a single frequency series or a frequency series associated with the bias frequency of the electrical bias energy among a plurality of frequency series respectively associated with a plurality of bias frequencies. The radio-frequency power supply may be configured to change the source frequency of the source radio-frequency power within the waveform period by sequentially using the plurality of frequencies as the source frequency of the source radio-frequency power within the waveform period.

In an embodiment, the bias power supply may periodically generate a pulse of voltage, as electrical bias energy, at time intervals having a time length that is a reciprocal of the bias frequency. The bias power supply may change at least one of a voltage level of the pulse and a duty ratio of the pulse at least once during the process.

In an embodiment, the radio-frequency power supply may adjust the frequency series in a frequency direction and in a time direction according to the voltage level of the pulse or a voltage level and a duty ratio of an electrode of the substrate support to which the pulse is supplied. The adjusted frequency series may be a single frequency series or a frequency series associated with the bias frequency of the electrical bias energy among a plurality of frequency series respectively associated with the plurality of bias frequencies. The radio-frequency power supply may be configured to change the source frequency of the source radio-frequency power within the waveform period by sequentially using a plurality of frequencies included in the adjusted frequency series as the source frequency of the source radio-frequency power within the waveform period.

In an embodiment, the bias power supply may decrease the bias frequency in a stepwise manner during the process. The process may be an etching process for a substrate disposed on a substrate support.

In an embodiment, the bias power supply may periodically generate a pulse of voltage, as electrical bias energy, at time intervals having a time length that is a reciprocal of the bias frequency. The bias power supply may perform at least one of increasing an absolute value of a level of a negative voltage of the pulse in a stepwise manner and decreasing a duty ratio of the pulse in a stepwise manner, during the process. The process may be an etching process for the substrate disposed on the substrate support.

In an embodiment, the bias power supply may generate bias radio-frequency power, as electrical bias energy. The bias power supply may increase a power level of the bias radio-frequency power during the process. The process may be an etching process for the substrate disposed on the substrate support.

In an embodiment, the bias power supply may increase the bias frequency in a stepwise manner during the process. The process may be a cleaning process of the chamber. The process may include an etching process for the substrate disposed on the substrate support and a cleaning process of the chamber performed after the etching process.

In an embodiment, the bias power supply may periodically generate a pulse of voltage, as electrical bias energy, at time intervals having a time length that is a reciprocal of the bias frequency. The bias power supply may perform at least one of decreasing the absolute value of the level of the negative voltage of the pulse in a stepwise manner and increasing the duty ratio of the pulse in a stepwise manner, during the process. The process may be a cleaning process of the chamber. The process may include an etching process for the substrate disposed on the substrate support and a cleaning process of the chamber performed after the etching process.

In an embodiment, the bias power supply may generate bias radio-frequency power as electrical bias energy. The bias power supply may decrease the power level of the bias radio-frequency power during the process. The process may be a cleaning process of the chamber. The process may include an etching process for the substrate disposed on the substrate support and a cleaning process of the chamber performed after the etching process.

In another embodiment, a power system is provided, which includes a bias power supply and a radio-frequency power supply. The bias power supply is configured to generate electrical bias energy that is supplied to the substrate support provided within the chamber of the plasma processing apparatus. The radio-frequency power supply is configured to generate source radio-frequency power to generate plasma from a gas within the chamber. The bias power supply is configured to change a bias frequency of the electrical bias energy at least once during a process. The radio-frequency power supply is configured to change a source frequency of the source radio-frequency power to reduce a degree of reflection of the source radio-frequency power within a waveform period of the electrical bias energy having a time length that is a reciprocal of the bias frequency, during the process.

In still another embodiment, a control method is provided, which includes (a) supplying electrical bias energy having a bias frequency from a bias power supply to a substrate support provided within a chamber of a plasma processing apparatus. The control method includes (b) supplying source radio-frequency power having a source frequency from a radio-frequency power supply to generate plasma from a gas within the chamber. In the (a) of a process, the bias frequency of the electrical bias energy is changed at least once. In the (b) of the process, the source frequency of the source radio-frequency power is changed to reduce a degree of reflection of the source radio-frequency power within a waveform period of the electrical bias energy having a time length that is a reciprocal of the bias frequency.

In still another embodiment, a program executed by a computer of the plasma processing apparatus is provided to execute the control method by the plasma processing apparatus. In still another embodiment, a storage medium for storing the program is provided.

Hereinafter, various embodiments will be described in detail with reference to the drawings. In addition, in each drawing, identical or equivalent portions are given the same reference numerals.

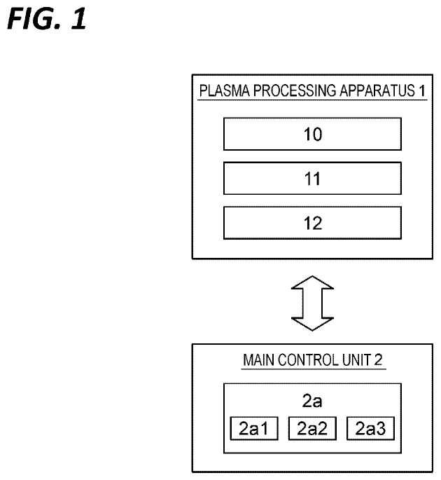

FIG. 1 illustrates a configuration of a plasma processing system according to an embodiment of the present disclosure. In an embodiment, the plasma processing system includes a plasma processing apparatus 1 and a main control unit 2. The plasma processing system is an example of a substrate processing system, and the plasma processing apparatus 1 is an example of a plasma processing apparatus. The plasma processing apparatus 1 includes a plasma processing chamber 10, a substrate support 11, and a plasma generating unit 12. The plasma processing chamber 10 includes a plasma processing space. The plasma processing chamber 10 also includes at least one gas inlet for supplying at least one processing gas to the plasma processing space, and at least one gas outlet for discharging a gas from the plasma processing space. The gas inlet is connected to a gas supply unit 20 to be described later, and the gas outlet is connected to an exhaust system 40 to be described later. The substrate support 11 is disposed in the plasma processing space and includes a substrate support surface for supporting a substrate.

The plasma generating unit 12 is configured to generate plasma from at least one processing gas supplied into the plasma processing space. The plasma formed in the plasma processing space may be a capacitively coupled plasma (CCP), an inductively coupled plasma (ICP), an electron-cyclotron-resonance plasma (ECR plasma), a helicon wave plasma (HWP), or a surface wave plasma (SWP).

The main control unit 2 processes computer-executable instructions that cause the plasma processing apparatus 1 to execute various processes described herein. The main control unit 2 may be configured to control each element of the plasma processing apparatus 1 to execute various processes described herein. In an embodiment, a portion or whole of the main control unit 2 may be included in the plasma processing apparatus 1. The main control unit 2 may include a processing unit 2a1, a storage unit 2a2 and a communication interface 2a3. The main control unit 2 is implemented, for example, by a computer 2a. The processing unit 2a1 may be configured to perform various control operations by reading a program from the storage unit 2a2 and executing the read program. The program includes computer-executable instructions that cause the plasma processing apparatus 1 to execute various processes of the control method according to an embodiment to be described later. The program may be stored in the storage unit 2a2 in advance, or may be acquired through a medium, when necessary. The acquired program is stored in the storage unit 2a2 and is read from the storage unit 2a2 by the processing unit 2a1 to be executed. The medium may be any of various storage mediums readable by the computer 2a, or may be a communication line that is connected to the communication interface 2a3. The processing unit 2a1 may be a central processing unit (CPU). The storage unit 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

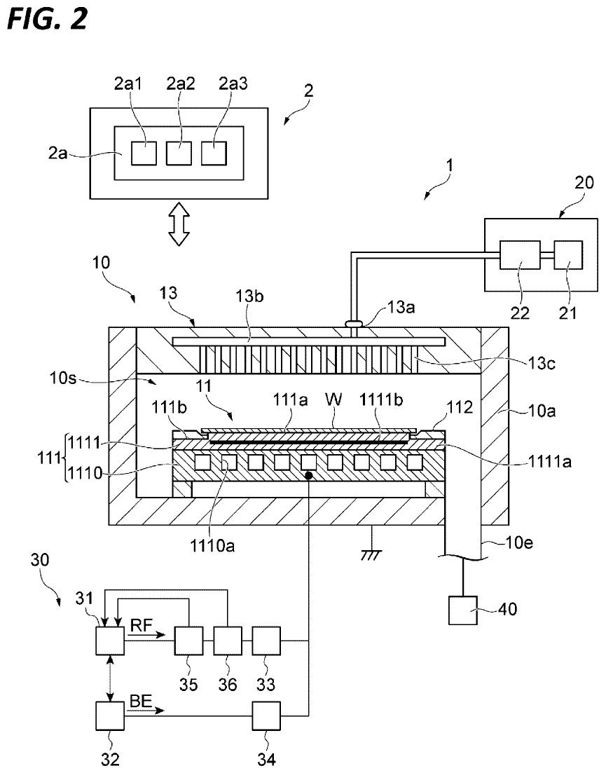

Hereinafter, an example of a configuration of a capacitively-coupled plasma processing apparatus as an example of the plasma processing apparatus 1 will be described. FIG. 2 illustrates a configuration of a capacitively coupled plasma processing apparatus according to an embodiment.

The capacitively-coupled plasma processing apparatus 1 includes the plasma processing chamber 10, the gas supply unit 20, a power system 30, and the exhaust system 40. The plasma processing apparatus 1 includes the substrate support 11 and a gas introduction unit. The gas introduction unit is configured to introduce at least one processing gas into the plasma processing chamber 10. The gas introduction unit includes a shower head 13. The substrate support 11 is disposed within the plasma processing chamber 10. The shower head 13 is disposed above the substrate support 11. In an embodiment, the shower head 13 constitutes at least a portion of a ceiling of the plasma processing chamber 10. The plasma processing chamber 10 includes a plasma processing space 10s defined by the shower head 13, side walls 10a of the plasma processing chamber 10, and the substrate support 11. The plasma processing chamber 10 is grounded. The substrate support 11 is electrically isolated from a casing body of the plasma processing chamber 10.

The substrate support 11 includes a body portion 111 and a ring assembly 112. The body portion 111 includes a central region 111a for supporting a substrate W and an annular region 111b for supporting the ring assembly 112. A wafer is an example of the substrate W. The annular region 111b of the body portion 111 surrounds the central region 111a of the body portion 111 as viewed in plan view. The substrate W is disposed on the central region 111a of the body portion 111, and the ring assembly 112 is disposed on the annular region 111b of the body portion 111 to surround the substrate W on the central region 111a of the body portion 111. Thus, the central region 111a may also be referred to as a substrate support surface for supporting the substrate W, and the annular region 111b may also be referred to as a ring support surface for supporting the ring assembly 112.

In an embodiment, the body portion 111 includes a base 1110 and an electrostatic chuck 1111. The base 1110 includes a conductive member. The electrostatic chuck 1111 is disposed on the base 1110. The electrostatic chuck 1111 includes a ceramic member 1111a and an electrostatic electrode 1111b disposed within the ceramic member 1111a. The ceramic member 1111a includes a central region 111a. In an embodiment, the ceramic member 1111a also includes an annular region 111b. Further, another member surrounding the electrostatic chuck 1111, such as an annular electrostatic chuck or an annular insulating member, may also have an annular region 111b. In this case, the ring assembly 112 may be disposed on the annular electrostatic chuck or annular insulating member, or may be disposed on both the electrostatic chuck 1111 and the annular insulating member.

The ring assembly 112 includes one or more annular members. In an embodiment, the one or more annular members include one or more edge rings and at least one cover ring. The edge rings are formed of a conductive material or an insulating material, and the cover ring is formed of an insulating material.

The substrate support 11 may include a temperature control module configured to regulate at least one of the electrostatic chuck 1111, the ring assembly 112, and the substrate to a target temperature. The temperature control module may include a heater, a heat transfer medium, a flow path 1110a, or a combination thereof. A heat transfer fluid, such as brine or gas, flows through the flow path 1110a. In an embodiment, the flow path 1110a is formed within the base 1110, and one or more heaters are disposed within the ceramic member 1111a of the electrostatic chuck 1111. The substrate support 11 may include a heat transfer gas supply configured to supply a heat transfer gas to a gap between a back surface of the substrate W and the central region 111a.

The shower head 13 is configured to introduce at least one processing gas from the gas supply unit 20 into the plasma processing space 10s. The shower head 13 includes at least one gas supply inlet 13a, at least one gas diffusion chamber 13b, and a plurality of gas introduction inlets 13c. A processing gas supplied to the gas supply inlet 13a, passes through the gas diffusion chamber 13b and is introduced into the plasma processing space 10s from the plurality of gas introduction inlets 13c. Further, the shower head 13 includes at least one upper electrode. The gas introduction unit may include one or more side gas injectors (SGI) attached to one or more openings formed in the side wall 10a, in addition to the shower head 13.

The gas supply unit 20 may include at least one gas source 21 and at least one flow controller 22. In an embodiment, the gas supply unit 20 is configured to supply at least one processing gas to the shower head 13 from the gas source 21 corresponding to each processing gas through the flow controller 22 corresponding to each processing gas. Each flow controller 22 may include, for example, a mass flow controller or a pressure-controlled flow controller. In addition, the gas supply unit 20 may include at least one flow modulation device for modulating or pulsing a flow of the at least one processing gas.

The exhaust system 40 may be connected to a gas outlet 10e, for example, provided at a bottom of the plasma processing chamber 10. The exhaust system 40 may include a pressure regulating valve and a vacuum pump. By the pressure regulating valve, a pressure in the plasma processing space 10s is regulated. The vacuum pump may include a turbomolecular pump, a dry pump, or a combination thereof.

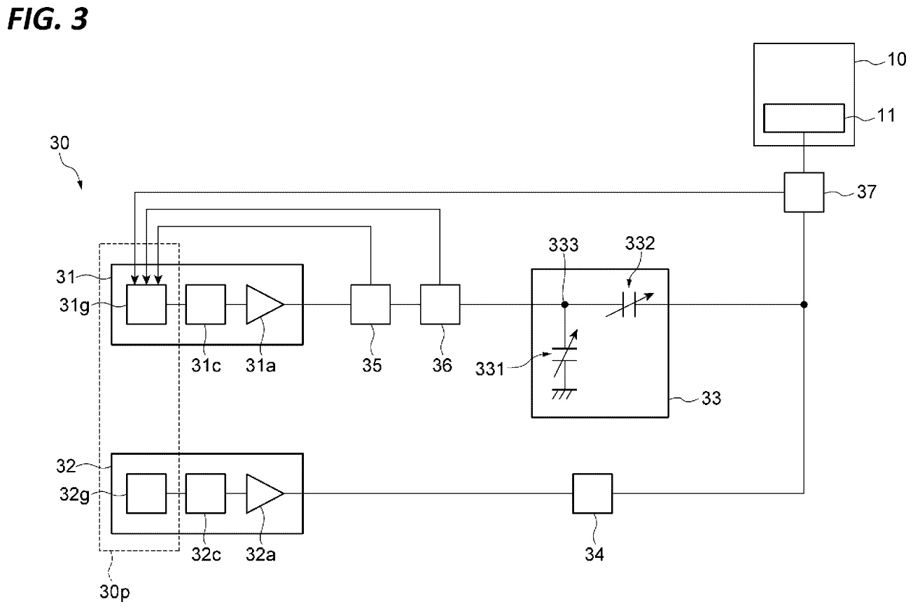

Hereinafter, FIG. 3 will be referred together with FIG. 2. FIG. 3 illustrates a configuration of the power system in the plasma processing apparatus according to an embodiment. The power system 30 includes a radio-frequency power supply 31 and a bias power supply 32. The radio-frequency power supply 31 constitutes the plasma generating unit 12 according to an embodiment. The radio-frequency power supply 31 is configured to generate source radio-frequency power RF. The source radio-frequency power RF has a source frequency f_{RF}. That is, the source radio-frequency power RF has a sinusoidal waveform whose frequency is the source frequency f_{RF}. The source frequency f_{RF} may be a frequency in a range of 10 MHz to 150 MHz. The radio-frequency power supply 31 is electrically connected to a radio-frequency electrode through a matching box 33 and is configured to supply the source radio-frequency power RF to the radio-frequency electrode. The radio-frequency electrode may be at least one electrode provided within the conductive member of the base 1110 or the ceramic member 1111a, or an upper electrode. When the source radio-frequency power RF is supplied to the radio-frequency electrode, plasma is generated from the gas within the chamber 10.

The matching box 33 has a variable impedance. The variable impedance of the matching box 33 is set to reduce reflection from a load of the source radio-frequency power RF. The matching box 33 may be controlled, for example, by the main control unit 2. In an embodiment, the matching box 33 may include a first variable condenser 331 and a second variable condenser 332. The first variable condenser 331 is connected between a node 333 and a ground. The node 333 is provided on a feed path connected between the radio-frequency power supply 31 and the radio-frequency electrode. The source radio-frequency power RF is supplied to the radio-frequency electrode via the feed path. The second variable condenser 332 is connected between the node 333 and the radio-frequency electrode. A capacitance C1 of the first variable condenser 331 and a capacitance C2 of the second variable condenser 332 may be controlled, for example, by the main control unit 2.

In an embodiment, the radio-frequency power supply 31 includes an oscillator 31g, a D/A converter 31c, and an amplifier 31a. The oscillator 31g generates a radio-frequency signal having a source frequency f_{RF}. The oscillator 31g may be a programmable device such as a field-programmable gate array (FPGA) or a processor. The oscillator 31g may be configured as a single programmable device 30p together with an oscillator 32g to be described later, or may be configured as a programmable device separate from the oscillator 32g.

An output of the oscillator 31g is connected to an input of the D/A converter 31c. The D/A converter 31c converts a radio-frequency signal from the oscillator 31g into an analog signal. An output of the D/A converter 31c is connected to an input of the amplifier 31a. The amplifier 31a amplifies the analog signal from the D/A converter 31c to generate the source radio-frequency power RF. An amplification rate of the amplifier 31a is specified to the radio-frequency power supply 31 from the main control unit 2. Also, the radio-frequency power supply 31 may not include the D/A converter 31c. In this case, the output of the oscillator 31g is connected to the input of the amplifier 31a, and the amplifier 31a amplifies the radio-frequency signal from the oscillator 31g to generate the source radio-frequency power RF.

The bias power supply 32 is configured to generate electrical bias energy BE. The bias power supply 32 is electrically coupled to the substrate support 11. The bias power supply 32 is electrically connected to a bias electrode within the substrate support 11 and is configured to supply the electrical bias energy BE to the bias electrode. The bias electrode may be at least one electrode provided within the conductive member of the base 1110 or the ceramic member 1111a. When the electrical bias energy BE is supplied to the bias electrode, ions from plasma are drawn to the substrate W.

The electrical bias energy BE has a bias frequency. The bias frequency is lower than the source frequency. The bias frequency may be a frequency in a range of 100 kHz to 60 MHz. Furthermore, the electrical bias energy BE has a waveform period, that is, a cycle CY. The cycle CY has a time length of a reciprocal of the bias frequency. The electrical bias energy BE is periodically supplied to the bias electrode in the cycles CY (at time intervals).

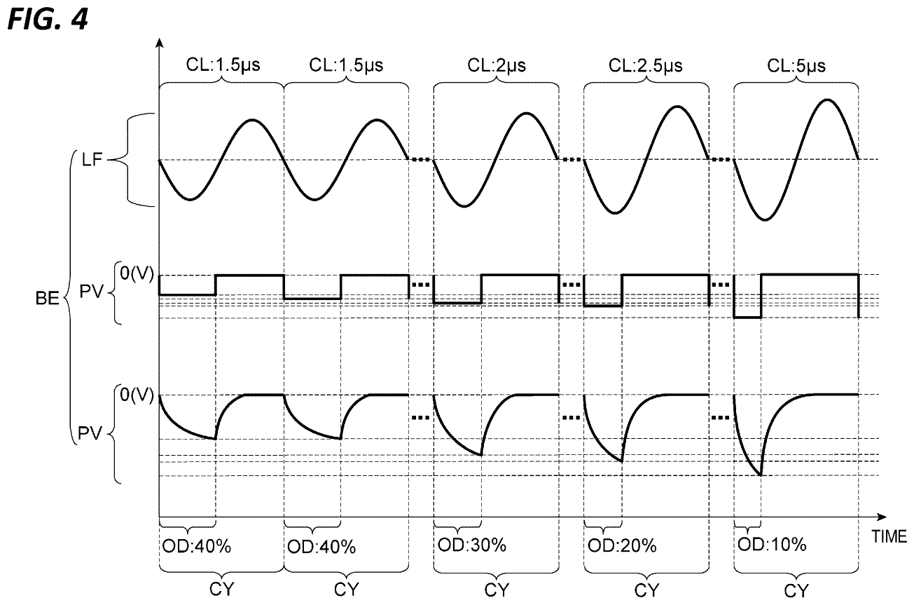

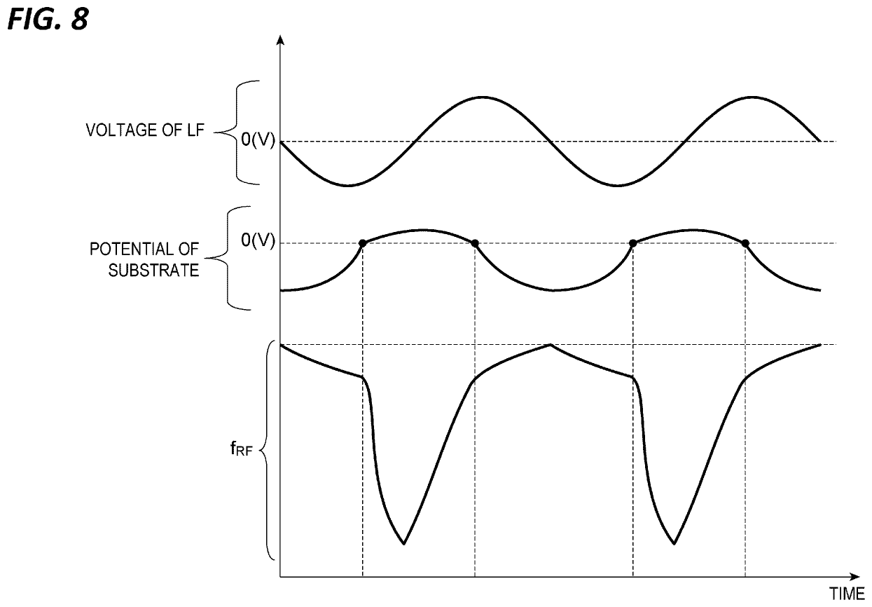

Hereinafter, FIGS. 4 to 8 are referred together with FIGS. 2 and 3. Each of FIGS. 4 to 8 illustrates a timing chart associated with a plasma processing apparatus according to an embodiment. The electrical bias energy BE may be a bias radio-frequency power LF having a bias frequency, as illustrated at the top of FIG. 4 and in FIG. 8. That is, the electrical bias energy BE may have a sinusoidal waveform whose frequency is the bias frequency. In this case, the bias power supply 32 is electrically connected to the bias electrode through a matching box 34. A variable impedance of the matching box 34 is set to reduce reflection from a load of the bias radio-frequency power supply LF.

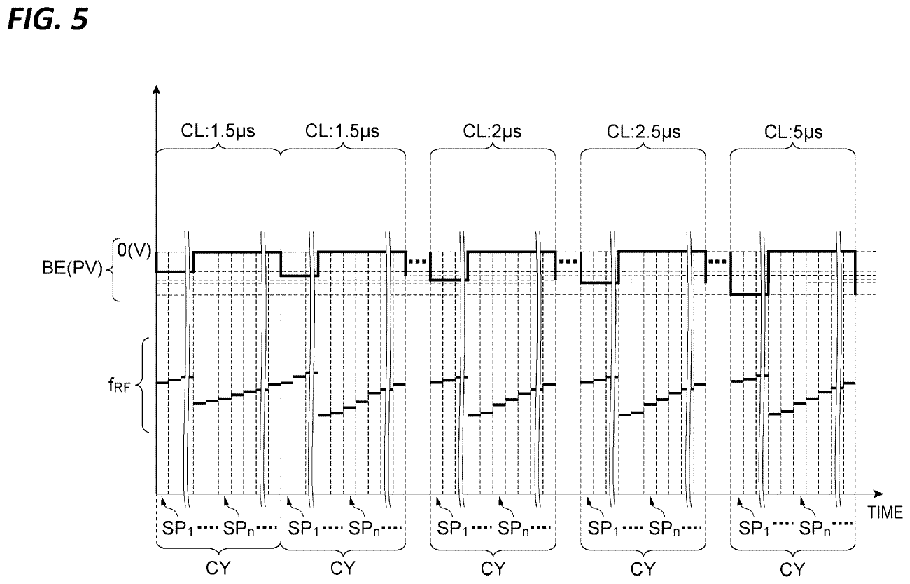

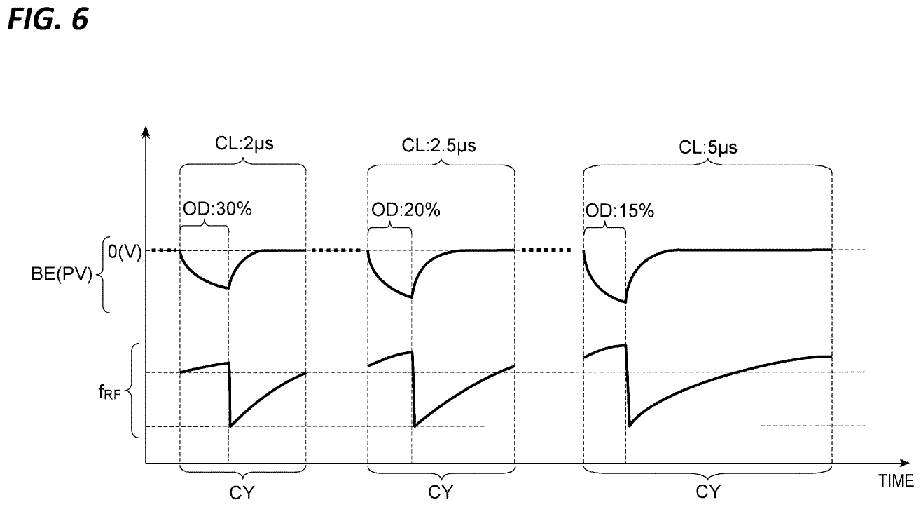

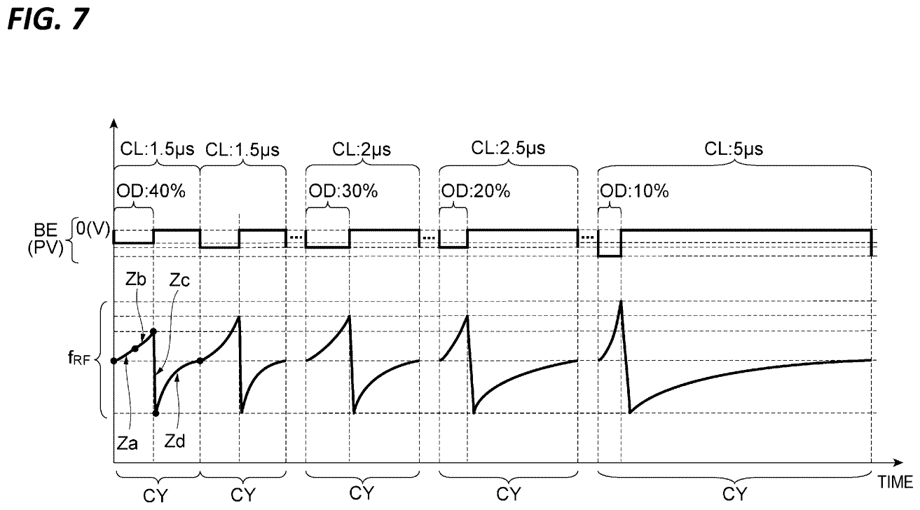

Alternatively, the electrical bias energy BE may include pulses PV of voltage, as illustrated in the middle of FIG. 4, in the bottom of FIG. 4, and in FIGS. 5 to 7. The pulse PV of voltage is applied to the bias electrode within each cycle CY. The pulse PV of voltage is periodically applied to the bias electrode at time intervals having a time length equal to a time length of the cycle CY. A waveform of the pulse PV may be a rectangular wave (e.g., “PV” indicated in the middle of FIG. 4, in FIG. 5, and in FIG. 7), a triangular wave, or any other waveform (e.g., “PV” indicated in the bottom of FIG. 4 and in FIG. 6). A polarity of the voltage of the pulse PV is set to cause a potential difference between the substrate W and the plasma to allow ions from the plasma to be drawn into the substrate W. The pulse PV may be, for example, a pulse of a negative voltage. Also, when the electrical bias energy BE is a pulse PV of voltage, the plasma processing apparatus 1 may not include the matching box 34.

As illustrated in FIGS. 4 to 7, the bias power supply 32 is configured to change the bias frequency of the electrical bias energy BE at least once during a process. That is, the bias power supply 32 is configured to change a time length CL of the cycle CY of the electrical bias energy BE at least once during the process. The time length CL is not limited to examples illustrated in FIGS. 4 to 7. The bias frequency and a timing for a change thereof are specified to the bias power supply 32 from the main control unit 2 based on recipe data.

When the electrical bias energy BE is the bias radio-frequency power LF, the bias power supply 32 may change a power level of the bias radio-frequency power LF at least once during the process, as illustrated in FIG. 4. The power level of the bias radio-frequency power LF and a timing for a change thereof are specified to the bias power supply 32 from the main control unit 2 based on the recipe data.

When the electrical bias energy BE is a pulse PV of voltage, the bias power supply 32 may change at least one of a voltage level of the pulse PV and a duty radio OD of the pulse PV at least once during the process, as illustrated in FIGS. 5 to 7. The duty ratio OD is a ratio or rate of a time length of an ON period where the pulse PV is output, to the time length CL of the cycle CY. The voltage level and the duty ratio OD of the pulse PV and a timing for changing them are specified to the bias power supply 32 from the main control unit 2 based on the recipe data. Within the cycle CY, a period other than the ON period may be an OFF period where the pulse PV is not output.

In an embodiment, as illustrated in FIG. 3, the bias power supply 32 includes the oscillator 32g, a D/A converter 32c, and an amplifier 32a. The oscillator 32g generates a bias signal having a specified bias frequency. The bias signal has a waveform period (e.g., cycle CY) having a time length of a reciprocal of the specified bias frequency, and is generated periodically in the cycles CY. The oscillator 32g may be a programmable device, such as a field-programmable gate array (FPGA) or a processor. The oscillator 32g may be configured as a single programmable device 30p together with the oscillator 31g, or may be configured as a programmable device separate from the oscillator 31g.

An output of the oscillator 32g is connected to an input of the D/A converter 32c. The D/A converter 32c converts a bias signal from the oscillator 32g into an analog signal. An output of the D/A converter 32c is connected to an input of the amplifier 32a. The amplifier 32a amplifies the analog signal from the D/A converter 32c to generate electrical bias energy BE. An amplification rate of the amplifier 32a is specified to the bias power supply 32 from the main control unit 2. The bias power supply 32 may not include the D/A converter 32c. In this case, the output of the oscillator 32g is connected to the input of the amplifier 32a, and the amplifier 32a amplifies a bias signal from the oscillator 32g to generate electrical bias energy BE.

In an embodiment, the bias power supply 32 may decrease the bias frequency in a stepwise manner during a process. That is, the bias power supply 32 may increase the time length CL of the cycle CY in a stepwise manner, as illustrated in FIGS. 4 to 7. In this case, the process may be an etching process for the substrate W (e.g., a film thereof) disposed on the substrate support 11. When the bias frequency is low, the energy of ions supplied to the substrate W increases. Thus, by decreasing the bias frequency in a stepwise manner during the etching process, it is possible to supply ions having high energy to the bottom of a deep hole of the substrate W to etch the substrate W. At the beginning of the etching process, the energy of the ions supplied to the substrate W is suppressed due to a high bias frequency. Thus, damage to a mask of the substrate W is inhibited.

In an embodiment, the bias power supply 32 may perform at least one of increasing an absolute value of a level of a negative voltage of the pulse PV in a stepwise manner and decreasing the duty ratio OD of the pulse PV in a stepwise manner during a process, as illustrated in FIGS. 4 to 7. The process may be an etching process for the substrate W disposed on the substrate support 11.

When the absolute value of the level of the negative voltage of the pulse PV is high, the energy of ions supplied to the substrate W increases. Accordingly, by increasing the absolute value of the level of the negative voltage of the pulse PV in a stepwise manner during the etching process, it is possible to supply ions having high energy to the bottom of a deep hole of the substrate W to etch the substrate W. At the beginning of the etching process, the energy of the ions supplied to the substrate W is suppressed due to a low absolute value of the level of the negative voltage of the pulse PV. Thus, damage to the mask of the substrate W is suppressed.

When the duty ratio OD is low, a time length of a period (i.e., the OFF period) in which an etch by-product is evacuated within the cycle CY extends. When the duty ratio OD is low, a time length of a period (e.g., the OFF period) in which deposits are formed on the mask of the substrate W within the cycle CY extends, and the amount of the deposits formed on the mask of the substrate W increases. Thus, by decreasing the duty ratio OD in a stepwise manner during the etching process, evacuation of the etch by-product from the bottom of the deep hole formed in the substrate W is facilitated. In addition, by decreasing the duty ratio OD in a stepwise manner during the etching process, the protection of the mask of the substrate W is facilitated by the deposits formed on the mask of the substrate W.

In an embodiment, the bias power supply 32 may increase the power level of the bias radio-frequency power LF during the process. The process may be an etching process for the substrate disposed on the substrate support 11. When the power level of the bias radio-frequency power LF is high, the energy of the ions supplied to the substrate W increases. Thus, by increasing the power level of the bias radio-frequency power LF in a stepwise manner during the etching process, it is possible to supply ions having high energy to the bottom of a deep hole of the substrate W to etch the substrate W. At the beginning of the etching process, due to a low power level of the bias radio-frequency power LF, the energy of the ions supplied to the substrate W is suppressed. Thus, damage to the mask of the substrate W is suppressed.

In an embodiment, the bias power supply 32 may increase the bias frequency in a stepwise manner during a process. The process may be a cleaning process of the chamber 10. In this case, at the beginning of the cleaning process, a low bias frequency is used. Accordingly, at the beginning of the cleaning process, cleaning of the chamber 10 is facilitated by ions with high energy. Additionally, by increasing the bias frequency in a stepwise manner during the cleaning process, damage to the components within the chamber 10 is reduced. Alternatively, the process may include an etching process for the substrate W disposed on the substrate support 11 and a cleaning process of the chamber 10 performed after the etching process. In this case, a low bias frequency is used in the etching process. Therefore, in the etching process, etching of the substrate W is facilitated by ions having high energy. In addition, in the cleaning process, a high bias frequency is used. Accordingly, in the cleaning process, damage to the components within the chamber 10 is reduced.

In an embodiment, the bias power supply 32 may perform at least one of decreasing the absolute value of the level of the negative voltage of the pulse PV in a stepwise manner and increasing the duty ratio OD of the pulse PV in a stepwise manner during the process. The process may be a cleaning process of the chamber 10. At the beginning of the cleaning process, a pulse PV having a relatively high absolute value of the level of the negative voltage is used. Thus, at the beginning of the cleaning process, cleaning of the chamber 10 is facilitated by ions having a relatively high energy. Additionally, by decreasing the absolute value of the level of the negative voltage of the pulse PV in a stepwise manner during the cleaning process, damage to the components within the chamber 10 is reduced. In addition, in the cleaning process, by increasing the duty ratio OD in a stepwise manner, cleaning of the chamber 10 is facilitated and damage to the components within the chamber 10 is reduced.

Alternatively, the process may include an etching process for the substrate W disposed on the substrate support 11 and a cleaning process of the chamber performed after the etching process. In this case, in the etching process, a pulse PV having a high absolute value of the level of the negative voltage is used. Thus, in the etching process, etching of the substrate W is facilitated by ions having relatively high energy. In addition, in the cleaning process, a pulse PV having a relatively low absolute value of the level of the negative voltage is used. Accordingly, in the cleaning process, damage to the components within the chamber 10 is reduced. Additionally, in the etching process, a pulse PV having a relatively low duty ratio OD is used, so that evacuation of an etch by-product is facilitated and protection of the mask of the substrate W is facilitated. In addition, by using a pulse PV with a relatively high duty ratio OD in the cleaning process, it is possible to clean the chamber 10 rapidly and suppress the damage to the components within the chamber 10.

In an embodiment, the bias power supply 32 may decrease the power level of the bias radio-frequency power LF during the process. The process may be a chamber cleaning process. In this case, at the beginning of the cleaning process, a bias radio-frequency power LF having a high power level is used. Thus, at the beginning of the cleaning process, cleaning of the chamber 10 is facilitated by ions having high energy. Also, by decreasing the power level of the bias radio-frequency power LF during the cleaning process, damage to components within the chamber 10 is reduced.

Alternatively, the process may include an etching process for the substrate W disposed on the substrate support 11 and a cleaning process of the chamber performed after the etching process. In this case, bias radio-frequency power LF having a relatively high power level is used in the etching process. Therefore, in the etching process, etching of the substrate W is facilitated by ions having relatively high energy. Also, in the cleaning process, bias radio-frequency power LF having a relatively low power level is used. Thus, in the cleaning process, damage to the components within the chamber 10 is reduced.

As illustrated in FIGS. 5 to 8, the radio-frequency power supply 31 is configured to change the source frequency f_{RF} of the source radio-frequency power RF within the cycle CY of the electrical bias energy BE to reduce a degree of reflection of the source radio-frequency power RF during the process.

In addition, when the pulse PV of voltage is used, a start time point of the cycle CY is identical to a start time point of a period of the pulse PV of voltage. Meanwhile, when the bias radio-frequency power LF is used, there is a difference between a start time point of a period of an output voltage of the bias power supply 32 and a start time point of a waveform period of a potential of the substrate W, as illustrated in FIG. 8. The potential of the substrate W may be a potential in a feed path that electrically connects the matching box 33 and the substrate support 11 (bias electrode) to each other, or may be measured by a potential sensor 37. When the bias radio-frequency power LF is used, the start time point of the cycle CY is determined from the measured potential of the substrate W. For example, a start time point at which the measured potential of the substrate W is 0 V is determined as the start time point of the cycle CY.

In an embodiment, the radio-frequency power supply 31 may divide each cycle CY into a plurality of phase periods SP, as illustrated in FIG. 5. In a plurality of cycles CY having different time lengths, the time length of each of the plurality of phase periods SP may be the same. Each of the plurality of cycles CY having different time lengths may be divided into the plurality of phase periods SP of the same number.

In an embodiment, the radio-frequency power supply 31 may use a plurality of frequency series, each associated with a plurality of settings of the electrical bias energy BE. Each of the plurality of settings of the electrical bias energy BE includes a bias frequency. Each of the plurality of settings of the electrical bias energy BE may further include a voltage level and/or duty ratio OD of the pulse PV. Alternatively, each of the plurality of settings of the electrical bias energy BE may include a power level of the bias radio-frequency power LF. Each of the plurality of frequency series may be predetermined to reduce a degree of the source radio-frequency power RF within the cycle CY when the electrical bias energy BE with a corresponding setting is supplied.

The radio-frequency power supply 31 uses, among the plurality of frequency series, a frequency series associated with the setting of the current electrical bias energy BE as a selected frequency series. Specifically, the radio-frequency power supply 31 sequentially uses, as the source frequency f_{RF}, a plurality of frequencies included in a frequency series (i.e., the selected frequency series) associated with the setting of the current electrical bias energy BE within the cycle CY of the electrical bias energy BE. For example, the radio-frequency power supply 31 uses a plurality of frequencies included in the selected frequency series as the source frequency f_{RF} for each of the plurality of phase periods SP within the cycle CY. The plurality of frequency series may be stored in a storage unit of the radio-frequency power supply 31 or may be provided to the radio-frequency power supply 31 from the main control unit 2. Alternatively, a frequency series associated with the setting of the current electrical bias energy BE may be provided to the radio-frequency power supply 31 from the main control unit 2, as the selected frequency series.

Alternatively, the radio-frequency power supply 31 may use a single frequency series. Specifically, the radio-frequency power supply 31 may sequentially use a plurality of frequencies included in a single frequency series, as the source frequency f_{RF}, within the cycle CY of the electrical bias energy BE. For example, the radio-frequency power supply 31 uses a plurality of frequencies included in a single frequency series as the source frequency f_{RF} for each of the plurality of phase periods SP within the cycle CY.

The radio-frequency power supply 31 may sequentially use a frequency series obtained by stretching a single frequency series in a time direction according to the bias frequency to be suitable for the time length CL of the cycle CY, as the source frequency f_{RF}, within the cycle CY. That is, the radio-frequency power supply 31 may adjust a time location within the cycle CY at which a plurality of frequencies included in the single frequency series is used as the source frequency f_{RF} according to the bias frequency.

In addition, the radio-frequency power supply 31 may sequentially use a plurality of frequencies included in a frequency series obtained by stretching a plurality of sections of the frequency series (e.g., a single frequency series) in the time direction according to the duty ratio OD, as the source frequency f_{RF}, within the cycle CY. That is, the radio-frequency power supply 31 may adjust a time location within the cycle CY in which the plurality of frequencies of each of the plurality of sections of the frequency series are used as the source frequency f_{RF}, to be suitable for a length of an ON period and a length of an OFF period of the pulse PV according to the duty ratio OD.

For example, as illustrated in FIG. 7, the frequency series may include four sections Za, Zb, Zc, and Zd. A time location within the cycle CY at which a plurality of frequencies included in the sections Za and Zb are used as the source frequency f_{RF} is adjusted to be suitable for the length of the ON period of the pulse PV. In addition, the time location within the cycle CY at which a plurality of frequencies included in the section Zd is used as the source frequency f_{RF} is adjusted to be suitable for the length of the OFF period of the pulse PV. A time location within the cycle CY at which the plurality of frequencies included in the section Zc is used as the source frequency f_{RF} is adjusted to be suitable for a period between a period where the section Zb is used and a period where the section Zc is used.

In addition, the radio-frequency power supply 31 may stretch a frequency series (e.g., a single frequency series) in the frequency direction according to a thickness of sheath (plasma sheath) on the substrate W. Each of the plurality of frequencies included in the frequency series is adjusted to be higher as the sheath on the substrate W at a time location within the cycle CY at which each frequency is used is thicker. The radio-frequency power supply 31 may sequentially use a plurality of frequencies included in the frequency series obtained by stretching in the frequency direction within the cycle CY, as the source frequency f_{RF}.

The sheath on the substrate W becomes thicker as a voltage level of the pulse PV or a voltage level of a bias electrode to which the pulse PV is supplied decreases (e.g., the voltage level increases in a negative direction). Thus, the radio-frequency power supply 31 may adjust each of the plurality of frequencies included in the frequency series according to the voltage level of the pulse PV or the voltage level of the bias electrode at the time location at which each frequency is used within the cycle CY.

The sheath on the substrate W becomes thicker as the potential of the substrate W set by the bias radio-frequency power LF decreases (e.g., the potential of the substrate W increases in a negative direction). Thus, the radio-frequency power supply 31 may adjust each of the plurality of frequencies included in the frequency series according to the potential of the substrate W at the time location within the cycle CY at which each frequency is used. Further, the potential of the substrate W may be measured by the potential sensor 37 as described above.

The radio-frequency power supply 31 may specify the source frequency f_{RF} that most suppresses the degree of reflection of the source radio-frequency power RF by changing the source frequency f_{RF} used in the same phase period SPₙ of each of a plurality of cycles CY having the same time length CL. The radio-frequency power supply 31 may use a specific source frequency f_{RF} in the phase period SPₙ. In addition, “n” in “SPₙ” indicates the order of phase periods within the cycle CY.

To determine the degree of reflection of the source radio-frequency power RF, the plasma processing apparatus 1 may further include a sensor 35 and/or a sensor 36. The sensor 35 is configured to measure a power level Pr of a reflected wave from a load of the source radio-frequency power RF. The sensor 35 includes, for example, a directional coupler. The directional coupler may be provided between the radio-frequency power supply 31 and the matching box 33. The sensor 35 may further be configured to measure a power level Pf of a traveling wave of the source radio-frequency power RF. The power level Pr of the reflected wave measured by the sensor 35 is informed to the radio-frequency power supply 31. Additionally, the power level Pf of the traveling wave may be informed to the radio-frequency power supply 31 from the sensor 35.

The sensor 36 includes a voltage sensor and a current sensor. The sensor 36 is configured to measure a voltage V_{RF} and a current I_{RF} in a feed path connecting the radio-frequency power supply 31 and the radio-frequency electrode to each other. The source radio-frequency power RF is supplied to the radio-frequency electrode via the feed path. The sensor 36 may be provided between the radio-frequency power supply 31 and the matching box 33. The voltage V_{RF} and the current I_{RF} in the feed path are informed to the radio-frequency power supply 31.

The radio-frequency power supply 31 generates representative values from measurement values in each of the plurality of phase periods SP. The measurement value may be a power levels Pr of a reflected wave acquired by the sensor 35. The measurement value may be a value of a ratio of the power level Pr of the reflected wave to an output power level of the source radio-frequency power RF. The measurement value may be a phase difference between a voltage and a current acquired by the sensor 36 in each of the plurality of phase periods SP. The representative value may be an average value or a maximum value of the above measurements in each of the plurality of phase periods SP. The radio-frequency power supply 31 uses the representative value in each of the plurality of phase periods SP as a value indicating the degree of reflection of the source radio-frequency power RF.

According to the plasma processing apparatus 1 described above, the bias frequency of the electrical bias energy BE changes as the process progresses during the process. Further, the source frequency f_{RF} is changed within the waveform period to reduce the degree of reflection of the source radio-frequency power RF within the waveform period (e.g., cycle CY) of the electrical bias energy BE. Thus, it is possible to change the bias frequency as the process progresses, and also, to reduce the degree of reflection of the source radio-frequency power RF.

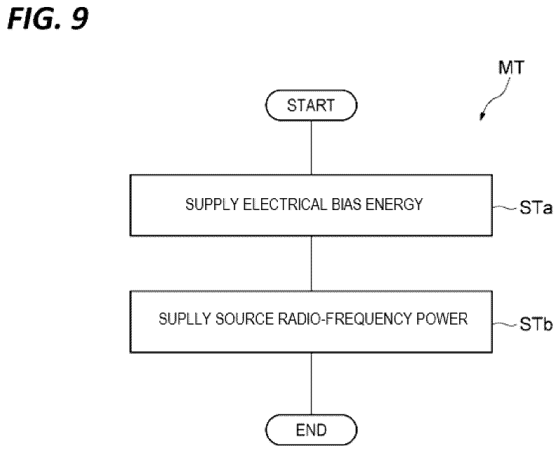

Hereinafter, a control method according to an embodiment will be described with reference to FIG. 9. FIG. 9 is a flowchart of a control method according to an embodiment. The control method (hereinafter, referred to as the “method MT”) illustrated in FIG. 9 includes a step Sta and a step STb. In the step Sta, electrical bias energy BE is supplied to the substrate support 11 (bias electrode) from the bias power supply 32. In the step STb, source radio-frequency power RF is supplied to a radio-frequency electrode to generate plasma from a gas within the chamber 10.

In the method MT, in the step Sta during a process, the bias frequency of the electrical bias energy BE is changed at least once. The change of the bias frequency of the electrical bias energy BE will be explained with reference to the foregoing description regarding the plasma processing apparatus 1.

In the method MT, in the step STb conducted during the process, the source frequency f_{RF} of the source radio-frequency power RF is changed to reduce the degree of reflection of the source radio-frequency power RF within a waveform period (e.g., cycle CY) of the electrical bias energy BE. The change of the source frequency f_{RF} within the cycle CY will be explained with reference to the foregoing description of the plasma processing apparatus 1.

While various embodiments have been described above, various additions, omissions, substitutions, and changes may be made without being limited to the embodiments described above. It is also possible to combine elements of different embodiments to form other embodiments.

In another embodiment, the plasma processing apparatus may be an inductively coupled plasma processing apparatus, an ECR plasma processing apparatus, a helical wave excitation plasma processing apparatus, or a surface wave plasma processing apparatus. In any of the plasma processing apparatuses, source radio-frequency power RF is used for the generation of plasma.

Furthermore, in the foregoing embodiments, the electrical bias energy BE is supplied continuously over a plurality of cycles CY. However, the electrical bias energy BE may be supplied in a plurality of pulse periods and may be stopped in periods between the plurality of pulse periods. Each of the plurality of pulse periods includes a plurality of cycles CY. In each of the plurality of pulse periods, the bias frequency of the electrical bias energy BE is changed at least once, as in the foregoing embodiments. The frequency series initially used by the radio-frequency power supply 31 in each of the plurality of pulse periods (selected frequency series or single frequency series described above) may be different from a sequency series initially used by the radio-frequency power supply 31 in other pulse periods of the plurality of pulse periods.

According to an embodiment, it is possible to change a bias frequency as a process progresses and also, to reduce a degree of reflection of source radio-frequency power.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A plasma processing apparatus comprising:
a chamber;
a substrate support disposed within the chamber;
a bias power supply electrically coupled to the substrate support and configured to generate electrical bias energy; and
a radio-frequency power supply electrically connected to a radio-frequency electrode and configured to generate source radio-frequency power, thereby generating plasma from a gas within the chamber,
wherein the bias power supply is configured to change a bias frequency of the electrical bias energy at least once during a process, and
the radio-frequency power supply is configured to change a source frequency of the source radio-frequency power to reduce a degree of reflection of the source radio-frequency power within a waveform period of the electrical bias energy having a time length that is a reciprocal of the bias frequency during the process.

2. The plasma processing apparatus according to claim 1, wherein the radio-frequency power supply is configured to change the source frequency of the source radio-frequency power within the waveform period, by sequentially using a plurality of frequencies included in a single frequency series or a frequency series associated with the bias frequency of the electrical bias energy among a plurality of frequency series respectively associated with a plurality of bias frequencies, as the source frequency of the source radio-frequency power within the waveform cycle.

3. The plasma processing apparatus according to claim 1, wherein the bias power supply is configured to:
periodically generate a pulse of voltage at time intervals having a time length that is a reciprocal of the bias frequency, as the electrical bias energy, and
change at least one of a voltage level of the pulse and a duty ratio of the pulse at least once, during the process.

4. The plasma processing apparatus according to claim 3, wherein the radio-frequency power supply is configured to change the source frequency of the source radio-frequency power within the waveform period, by sequentially using a plurality of frequencies obtained by adjusting a single frequency series or a frequency series associated with the bias frequency of the electrical bias energy among a plurality of frequency series respectively associated with a plurality of bias frequencies, in a frequency direction and in a time direction according to the voltage level of the pulse or a voltage level of an electrode of the substrate support to which the pulse is supplied, and the duty ratio.

5. The plasma processing apparatus according to claim 1, wherein the bias power supply is configured to decrease the bias frequency in a stepwise manner during the process.

6. The plasma processing apparatus according to claim 5, wherein the bias power supply is configured to:
periodically generate a pulse of voltage at time intervals having a time length that is a reciprocal of the bias frequency, as the electrical bias energy, and
perform at least one of increasing an absolute value of a level of a negative voltage of the pulse in a stepwise manner and decreasing a duty ratio of the pulse in a stepwise manner, during the process.

7. The plasma processing apparatus according to claim 5, wherein the bias power supply is configured to:
generate bias radio-frequency power as the electrical bias energy; and
increase a power level of the bias radio-frequency power, during the process.

8. The plasma processing apparatus according to claim 1, wherein the bias power supply is configured to increase the bias frequency in a stepwise manner during the process.

9. The plasma processing apparatus according to claim 8, wherein the bias power supply is configured to:
periodically generate a pulse of voltage at time intervals having a time length that is a reciprocal of the bias frequency, as the electrical bias energy, and
perform at least one of decreasing an absolute value of a level of a negative voltage of the pulse in a stepwise manner and increasing a duty ratio of the pulse in a stepwise manner, during the process.

10. The plasma processing apparatus according to claim 8, wherein the bias power supply is configured to:
generate bias radio-frequency power as the electrical bias energy; and
reduce a power level of the bias radio-frequency power, during the process.

11. A power system comprising:
a bias power supply configured to generate electrical bias energy supplied to a substrate support provided within a chamber of a plasma processing apparatus; and
a radio-frequency power supply configured to generate source radio-frequency power, thereby generating plasma from a gas within the chamber,
wherein the bias power supply is configured to change a bias frequency of the electrical bias energy at least once during the process, and
the radio-frequency power supply is configured to change a source frequency of the source radio-frequency power to reduce a degree of reflection of the source radio-frequency power within a waveform period of the electrical bias energy having a time length that is a reciprocal of the bias frequency, during the process.

12. A control method comprising:
(a) supplying electrical bias energy having a bias frequency from a bias power supply to a substrate support provided within a chamber of a plasma processing apparatus; and
(b) supplying source radio-frequency power having a source frequency from a radio-frequency power supply, thereby generating plasma from a gas within the chamber,
wherein in the (a) during a process, the bias frequency of the electrical bias energy is changed at least once, and
in the (b) during the process, the source frequency of the source radio-frequency power is changed to reduce a degree of reflection of the source radio-frequency power within a waveform period of the electrical bias energy having a time length that is a reciprocal of the bias frequency.

13. A non-transitory computer-readable storage medium having stored therein a program that causes a computer to execute a control method including:
(a) supplying electrical bias energy having a bias frequency from a bias power supply to a substrate support provided within a chamber of a plasma processing apparatus; and
(b) supplying source radio-frequency power having a source frequency from a radio-frequency power supply, thereby generating plasma from a gas within the chamber,
wherein in the (a) during a process, the bias frequency of the electrical bias energy is changed at least once, and
in the (b) during the process, the source frequency of the source radio-frequency power is changed to reduce a degree of reflection of the source radio-frequency power within a waveform period of the electrical bias energy having a time length that is a reciprocal of the bias frequency.
